(19) United States
(12) Patent Application Publication
(10) Pub. No.: US 2026/0006880 A1
(43) Pub. Date: Jan. 1, 2026

(54) FABRICATION OF TRENCH TRANSISTOR WITH ESD IN TRENCH

(71) Applicant: Alpha and Omega Semiconductor International LP, Toronto (CA)

(72) Inventors: Xueqing Liu, San Jose, CA (US); Qinhai Jin, Portland, OR (US); Sik Lui, Sunnyvale, CA (US); Xiaobin Wang, San Jose, CA (US); Wenwen Li, Santa Clara, CA (US); Lingpeng Guan, San Jose, CA (US); Madhur Bobde, Sunnyvale, CA (US); Jian Wang, Portland, OR (US); Sekar Ramamoorthy, Beaverton, OR (US)

(21) Appl. No.: 18/759,690

(22) Filed: Jun. 28, 2024

(51) Int. Cl. H01L 29/40; H01L 21/02; H01L 21/304; H01L 21/768; H01L 27/02; H01L 29/423

(52) U.S. Cl. CPC H10D 64/118; H01L 21/0254; H01L 21/304; H01L 21/76831; H10D 64/513; H10D 89/611

(57) ABSTRACT

A method of fabrication and composition of matter, comprising a semiconductor substrate including ions of a first conductivity type wherein the ions of the first conductivity are opposite ions of a second conductivity type, An Electrostatic Discharge Protection (ESD) trench formed in the semiconductor substrate with a lower insulation layer formed over a surface of the ESD trench in the semiconductor substrate. A nitride layer is formed over the lower insulation layer in the ESD trench, and an upper insulation is formed on the nitride layer in the ESD trench. An ESD semiconductor layer is formed on the upper insulation layer.

### FIELD OF THE DISCLOSURE

Aspects of the present disclosure relate to electrostatic discharge protection in transistor devices specifically aspects of the present disclosure relate to electrostatic discharge protection in trench transistor devices.

### BACKGROUND OF THE DISCLOSURE

An electrostatic discharge is a sudden and momentary flow of electrical current from one object to another object. Electrostatic discharge creates very high current and voltage that lasts a short period of time sometimes referred to as high voltage transients. In most cases the momentary nature of the electrostatic discharge allows the current to quickly dissipate over the surface of objects without causing damage. This is not the case for electronic devices such as transistors which are susceptible to high voltage transients. In transistors, high voltage transients may cause a breakdown in the insulation layers of the device resulting in a failure.

Transistor devices employ many techniques to protect the active area of the device from high voltage transients. Transistor devices may be encased in a grounded housing to protect the device from outside transients. A grounded housing may not be suitable for all applications and further takes up a lot of space compared to the transistor itself. Thus, transistor manufacturers have developed solutions for electrostatic discharge protection (ESD) that are integrated into the transistor device itself.

Previous implementations of ESD have implemented diode structures on the semiconductor substrate of the transistor devices. These prior structures include shallow trench junction diodes that have insulation formed during creation of the gate oxide layer.

It is within this context that aspects of the present disclosure arise.

### BRIEF DESCRIPTION OF THE DRAWINGS

The teachings of the present disclosure can be readily understood by considering the following detailed description in conjunction with the accompanying drawings, in which:

FIG. 1 depicts a cut-away side view of a transistor device having improved ESD trench with a nitride layer and a depression on the surface interface of the ESD semiconductor layer according to an aspect of the present disclosure.

FIG. 2 depicts a cut-away side view of a transistor device having improved ESD trench with a nitride layer and an active region gate trench that is etched independently of the ESD trench according to an aspect of the present disclosure.

FIG. 3 depicts a cut-away side view of a transistor device having improved ESD trench with a nitride layer having an active region formed after the formation of the ESD trench according to an aspect of the present disclosure.

FIGS. 4A-4I depict a method of fabrication of a transistor device having improved ESD trench with a nitride layer and a depression on the surface interface of the ESD semiconductor layer according to an aspect of the present disclosure.

FIGS. 5A-5I depict a method of fabrication of an improved transistor device with a nitride layer and an active region gate trench that runs deeper into the semiconductor substrate than the ESD trench layer according to an aspect of the present disclosure.

FIGS. 6A-6G depict a method of fabrication of a transistor device having improved ESD trench with a nitride layer having an active region formed after the formation of the ESD trench 3 according to an aspect of the present disclosure.

### DESCRIPTION OF THE SPECIFIC EMBODIMENTS

Although the following detailed description contains many specific details for the purposes of illustration, anyone of ordinary skill in the art will appreciate that many variations and alterations to the following details are within the scope of the invention. Accordingly, examples of embodiments of the invention described below are set forth without any loss of generality to, and without imposing limitations upon, the claimed invention. In the following Detailed Description, reference is made to the accompanying drawings, which form a part hereof, and in which are shown by way of illustration specific embodiments in which the invention may be practiced. In this regard, directional terminology, such as “top,” “bottom,” “front,” “back,” “leading,” “trailing,” etc., is used with reference to the orientation of the figure(s) being described. Because components of embodiments of the present disclosure can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

The disclosure herein refers to a semiconductor material, such as silicon, doped with ions of a first conductivity type or a second conductivity type. The ions of the first conductivity type may be opposite ions of the second conductivity type. For example, and without limitation, in some implementations, ions of the first conductivity type may be n-type, which contribute negative charge carriers, e.g., electrons, when doped into silicon. In such implementations, ions of the first conductivity type may include phosphorus, antimony, bismuth, lithium, and arsenic. In such implementations, ions of the second conductivity may be p-type, which create holes for charge carriers when doped into silicon and in this way are referred to as being the opposite of n-type. P-type ions include boron, aluminum, gallium, and indium. While the above description referred to n-type as the first conductivity type and p-type as the second conductivity type the disclosure is not so limited, p-type may be the first conductivity type and n-type may be the second conductivity type. Furthermore, semiconductor materials other than silicon may be used in MOSFET devices in accordance with aspects of the present disclosure.

In the following Detailed Description, reference is made to the accompanying drawings, which form a part hereof, and in which are shown by way of illustration of specific embodiments in which the invention may be practiced. For convenience, use of + or − after a designation of conductivity or net impurity carrier type (p or n) refers generally to a relative degree of concentration of a designated type of net impurity carriers within a semiconductor material. In general, terms, an n+ material has a higher n type net dopant (e.g., electron) concentration than an n material, and an n material has a higher carrier concentration than an n-material. Similarly, a p+ material has a higher p type net dopant (e.g., hole) concentration than a p material, and a p material has a higher concentration than a p− material. It is noted that what is relevant is the net concentration of the carriers, not necessarily dopant concentration. For example, a material may be heavily doped with n-type dopants but still have a relatively low net carrier concentration if the material is also sufficiently counter-doped with p-type dopants. As used herein, a concentration of dopants less than about 1e¹⁶ cm⁻³ may be regarded as “lightly doped” and a concentration of dopants greater than about 1e¹⁷ cm⁻³ may be regarded as “heavily doped”.

Prior implementations create insulation in an ESD during the same formation step as the creation of the gate oxide. This saves on steps during fabrication, but it has been found that the oxide layer created in the ESD during this step is insufficient to insulate the ESD trench from the transients at smaller ESD trench widths. Thus, in the previous implementations a large amount of the substrate area must be taken up by the ESD trench to provide sufficient protection against high voltage transients.

Having recognized this issue, a trench ESD structure is proposed having a thick bottom insulation with a nitride layer according to aspects of the present disclosure. The thick ESD semiconductor layer with bottom insulation plus nitride layer improves the resistance of the ESD structure to leakage of high voltage transients into the active area, thereby reducing the area of the substrate required for ESD trenches. As such multiple methods of production for a transistor device having an ESD trench with nitride layer in the ESD trench are provided herein.

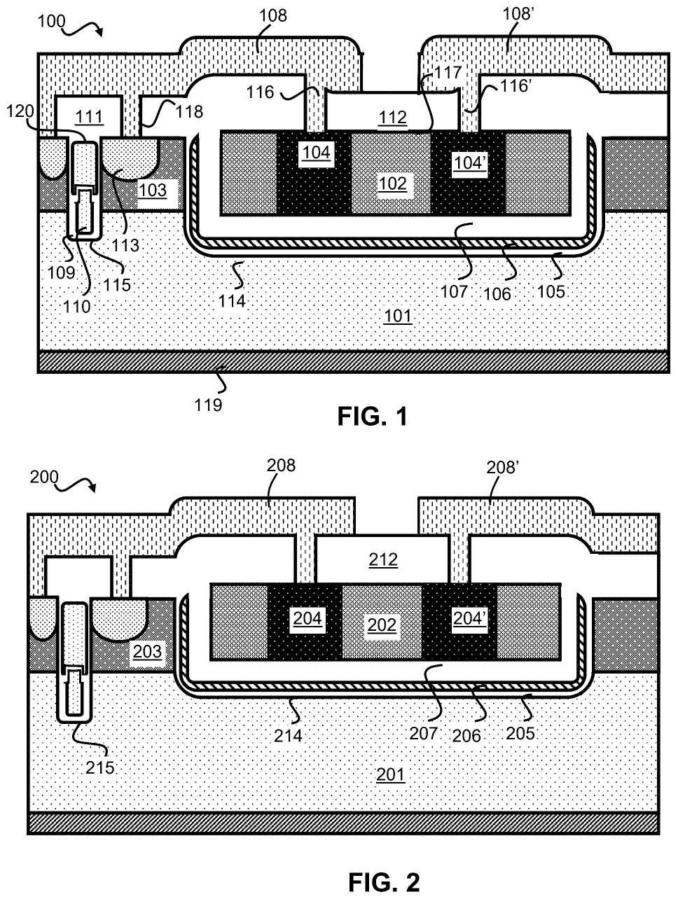

As shown in FIG. 1, an improved transistor device 100 according to aspects of the present disclosure may include an ESD trench 114 and an active region gate trench 115 formed in a semiconductor substrate 101. The ESD trench 114 as shown is lined with a lower ESD insulation layer 105, a nitride layer 106 and an upper ESD insulation layer 107. An ESD semiconductor layer 102 is formed on the upper ESD insulation layer 107. The upper ESD insulation material 107 and lower ESD insulation material may be made from any suitable electrically insulating material for example and without limitation, silicon dioxide. In this implementation the semiconductor substrate 101 may be doped with ions of a first conductivity type, for example n-type ions. The ESD semiconductor layer 102 may be a conductive material such as polycrystalline silicon doped with ions of a second conductivity type, for example p-type ions. The ESD semiconductor layer may also include ESD contact regions 104 doped with ions of the first conductivity type. The ESD contact regions 104 may act as a cathode for a junction diode formed between the contact region and the doped ESD semiconductor layer 102. In this configuration the doped ESD semiconductor layer may act as the anode. A source metal layer 108 may make contact with a first ESD contact region 104 through vias 116 in the top portion of the ESD trench insulation layer 112. A gate metal layer 108′ may make contact with a second ESD contact region 104′ through vias 116′ in the top portion of the ESD trench insulation layer 112 thus forming a back to back ESD diode between the gate and the source.

The improved transistor device 100 also includes traditional transistor components such as gate insulation layer 109 formed in the active gate trench 115 and gate electrode 120 formed over top insulation of a shield electrode 110. The shield electrode 110 is formed in a bottom portion of the active gate trench 115 over the gate insulation layer 109. The semiconductor substrate 101 may have body regions 103 doped with ions of the second conductivity type formed in an upper portion of the substrate. A source region 113 may be formed in a portion of the body region 103 near the gate trench 115 and heavily doped with ions of the first conductivity type.

The embodiment shown in FIG. 1 is a shielded gate trench (SGT) implementation where the gate insulation layer 109 includes a thin upper portion separating the gate electrode 120 from the body region 103 and the source region 113, a thick lower portion at the gate trench 115 surrounding the shield electrode 110, and an inter-electrode dielectric portion separating the gate electrode 120 from the shield electrode 110. Alternatively, in single gate electrode implementations (not shown), the gate electrode 120 may be directly connected to the shield electrode 110 without the middle portion of insulation separating therein as that shown in FIG. 1.

Vias 118 in the top gate insulation layer 111 allows the source metal 108 to make conductive contact with the source contact region 113. The body region 103 is in contact with the source metal through vias in the top insulation to form the anti-parallel body diode in this transistor device this region is not shown in the current view but may be formed during a separate masking, etch and deposition step or at during the same steps which created conductive contact with the source region. As shown, the vias 118 are only formed through the top gate insulation layer 111 to make electrically conductive contact with the source region 113. Alternatively, the vias 118 may extend into the source region 113 or even through the source region 113 to also contact the body region 103. A drain metal 119 may be formed on the backside of the device and a gate contact (not shown) may be made to the gate electrode allowing control of the gate of the transistor device. While the present disclosure discusses transistor devices with a shield electrode it should be understood that aspects of the present disclosure are not so limited and maybe extended to transistor structures without shield electrodes.

The overall layout of the transistor device shown in FIGS. 2-4 are similar to the layout shown in FIG. 1 thus they will be discussed by way of the structural differences between the devices and the device shown in FIG. 1. These differences may arise due to the differences in the fabrication process steps between the devices as will be discussed in a later section.

FIG. 2 depicts an example of a transistor device 200 having improved ESD trench with nitride layer and an active region gate trench that is etched independently of the ESD trench according to an aspect of the present disclosure. In this implementation the ESD trench 214 may be any arbitrary depth as it is created in a step independent of the creation of Active gate trench 215. Here the ESD trench 214 is depicted as shallower than the active gate trench 215 to differentiate this depiction from the depiction of the implementation shown in FIG. 1. Thus, the respective lower ESD insulation layer 205, nitride layer 206 and upper ESD insulation layer 207 are shallower in the substrate composition due to the shallow ESD trench. The top of the ESD semiconductor layer 202 may additionally be formed above a top of the body region 203 of the semiconductor substrate composition 201. This shallow trench is the result of a manufacture process that forms the active gate trench 215 before the ESD trench 214. This results in a more regular shaped rectangular ESD semiconductor layer 202 without the depression seen in the semiconductor layer 102 of FIG. 1. This may cause a small rise in the top ESD insulation layer 212 over the surface of the substrate composition, likewise the conductive source metal 208 may follow this rise over the ESD trench. As with the device shown in FIG. 1, the source metal layer 208 may make contact with a first ESD contact region 204 through vias in the top portion of the top ESD insulation layer 212. A gate metal layer 208′ may make contact with a second ESD contact region 204′ through vias in the top portion of the ESD trench insulation layer 212 thus forming a back to back ESD diode between the gate and the source.

It should further be understood that the ESD trench can have arbitrary depth, even deeper than the active region gate trench; because it is etched independently unlike in FIG. 1 where both trenches are etched at the same time and thus the ESD trench must be substantially deeper than the active region gate trench and cannot have arbitrary depth.

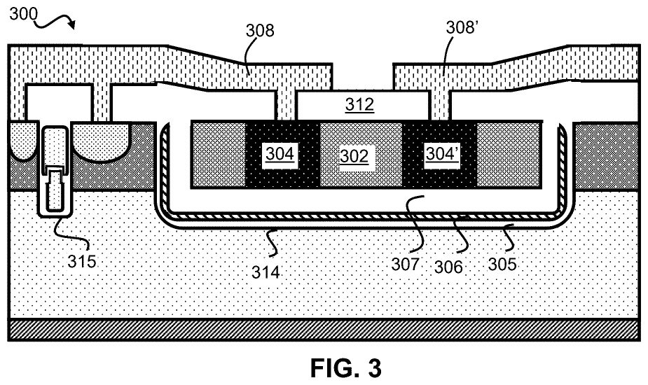

FIG. 3 depicts a cut-away side view of a transistor device 300 having improved ESD trench with nitride layer having an active region formed after the formation of the ESD trench according to an aspect of the present disclosure. In the implementation shown the ESD trench 314 is formed before the active gate trench 315. It should be understood that because the ESD trench 314 is formed independently of the active gate trench 315 it may have any arbitrary depth and this implementation is not limited to ESD trenches and active trenches having similar depths. Additionally, the ESD semiconductor layer 302 is substantially rectangular with no additional side conductive side structures in the ESD trench. The lower ESD insulation layer 305, nitride layer 306 and upper ESD insulation layer 307 may line the ESD trench 314 with a continuous ESD semiconductor layer 302 formed on top of the upper ESD insulation layer 307. The top ESD insulation layer 312 may have a depression in the upper portion created during the manufacturing process. The source metal 308 may likewise include a depression following the contour of the ESD insulation layer 312. As with the devices shown in FIG. 1 and FIG. 2, the source metal layer 308 may make contact with a first ESD contact region 304 through vias in the top portion of the top ESD insulation layer 312. A gate metal layer 308′ may make contact with a second ESD contact region 304′ through vias in the top portion of the ESD trench insulation layer 312 thus forming a back to back ESD diode between the gate and the source.

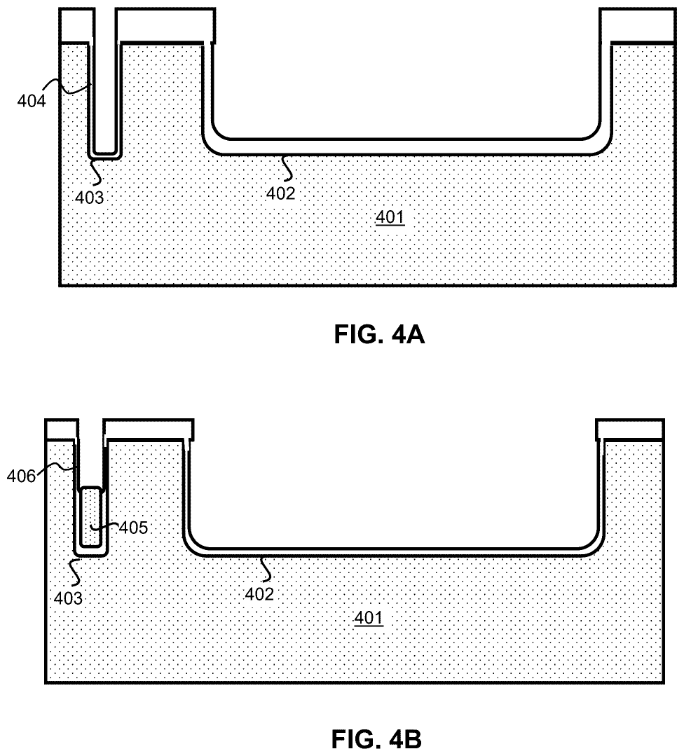

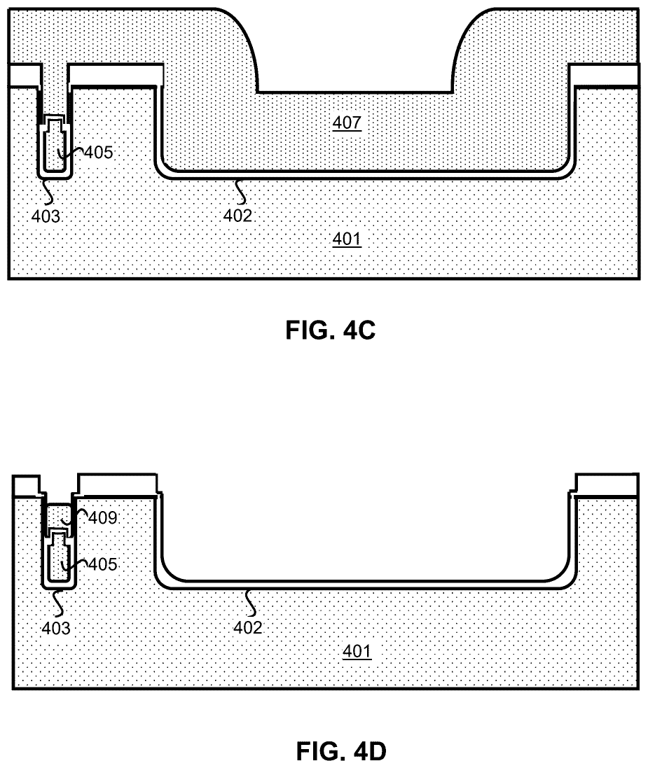

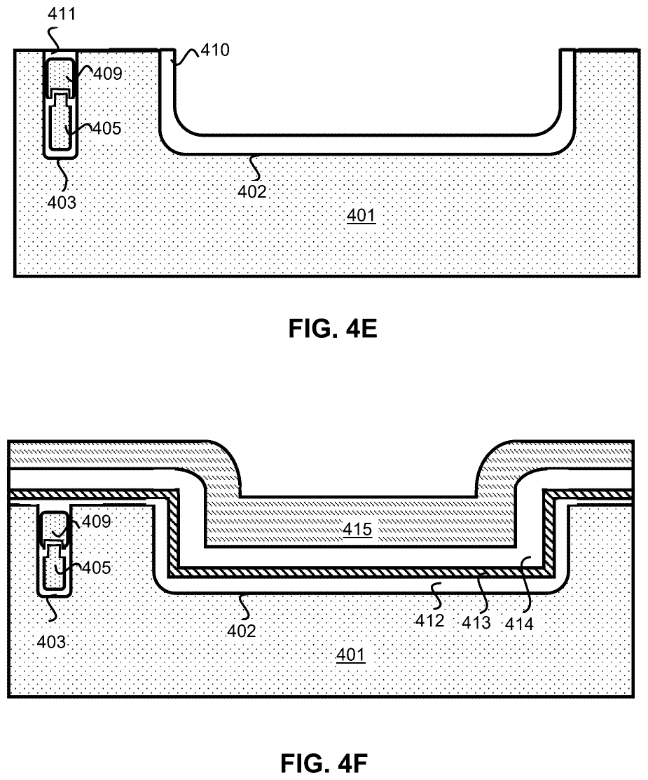

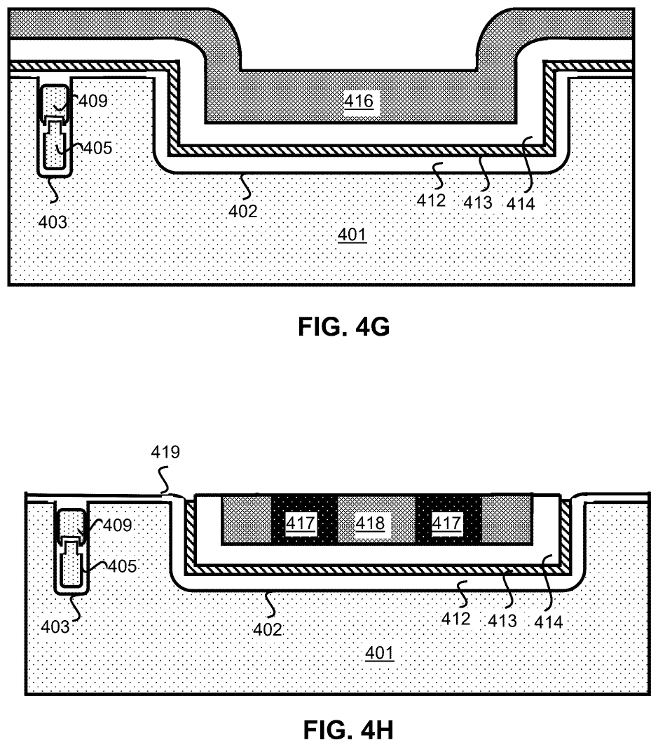

FIGS. 4A-4I depict a method of fabrication of a transistor device having improved ESD trench with nitride layer and a depression on the surface interface of the ESD semiconductor layer of the type shown in FIG. 1. In this fabrication method, an ESD trench 402 and active gate trench 403 are formed in a semiconductor substrate 401 during the same etching step as shown in FIG. 4A. The semiconductor substrate 401 may include an epitaxial layer lightly doped with ions of a first conductivity type formed on top of a heavily doped layer of the first conductivity type. The semiconductor substrate 401 is masked with an oxide hard mask and then the ESD trench 402 and Active Gate trench 403 are etched by a suitable trench formation method for example and without limitation, an anisotropic process such as reactive ion etching (RIE), an isotropic etch may further be applied to create a rounded bottom for the active gate trench. The isotropic etch may be performed using any suitable isotropic etch such as Nitrous acid (HNO₂), Hydrofluoric acid (HF), Acetic acid (CH₃COOH) or any combination thereof. After etching the trenches an oxide layer 404 is formed, e.g., by thermal oxidation or by deposition, over the top surface of the substrate composition including the exposed surfaces in the trenches.

Next as shown in FIG. 4B a blanket n-doped polysilicon layer is deposited over the entire top surface of the substrate composition to fill up the active gate trench 403 with a polysilicon layer 405. The blanket n-doped polysilicon layer is then etched away from the top surface, the ESD trench and an upper portion of the active gate trench 403, forming the shield electrode 405 in the bottom portion of the active trench 403. The oxide layer 404 on the upper side wall within an upper portion of the active gate trench 403 not covered by the shield electrode 405 is then removed by wet etch. The substrate is then oxidized to form an inter-poly oxide on top of the shield electrode 405 and a thin oxide layer 406 on the upper side wall of the active gate trench 404. The thin oxide layer also layers the sides of the upper portion of the ESD trench 403 and adds to the thickness of the oxide layer on the top surface of the substrate composition.

In single gate electrode implementations, the lower active gate polysilicon forming shield electrode 405 may be etched away in the active gate trench right after the oxide layer 404 in the upper portion of the active gate trench is removed, leaving the lower portion of the oxide layer 404 in the active gate trench 403. The substrate may then be oxidized to form a thin oxide layer 406 on the upper side wall of the active gate trench 404.

Next an n-doped polysilicon layer 407 is deposited over the top surface of the substrate composition including in the Active gate trench 403 and ESD trench 402 as shown in FIG. 4C. This will form the upper gate electrode and may be formed by any suitable deposition method such as chemical vapor deposition (CVD), Physical Vapor Deposition (PVD) etc. As shown in FIG. 4D the polysilicon layer is etched back completely from the top surface of the substrate composition and the ESD trench 402 leaving the top gate electrode layer 409 in the gate trench 403.

An optional oxide layer may be deposited over the exposed surface of the substrate composition by any suitable deposition method, for example and without limitation CVD, thermal oxidation and the like. The optional oxide layer and the hard mask layer are then removed from the top surface of the substrate composition via chemical and mechanical polishing (CMP). As shown in FIG. 4E the result is a portion of lower ESD trench oxide layer 410 formed in the ESD trench 402 and a top gate oxide layer 411.

Next FIG. 4F shows an additional oxide material deposited over the surface of the substrate composition forming the full lower ESD trench oxide layer 412 in the ESD trench. Followed by deposition of a nitride layer 413 and then an upper ESD oxide layer 414 deposited in the ESD trench 402 and over the top surface of the substrate composition. Finally, ESD semiconductor layer 415 is deposited over the upper ESD oxide layer 414 in the ESD trench 402 and over the top surface of the substrate composition. The ESD semiconductor layer 415, upper ESD insulation layer 414, nitride layer 413 and lower ESD insulation layer 412 may be formed by any suitable deposition method for example and without limitation CVD. The ESD semiconductor layer 415 may be undoped polycrystalline silicon, which is subsequently doped with ions of the second conductivity type as shown in FIG. 4G. Alternatively, this step may be carried out at the same time as doping the body region. The doped ESD semiconductor layer 416 is heated to drive the ions of the second conductivity type to diffuse throughout the semiconductor layer. Drive of the ions as discussed above may be performed by any suitable thermal drive method for example and without limitation, heating the substrate composition at between 900-1500° C. for up to an hour, e.g., 1050° C. for 30 minutes. Thermal drive performed here generally requires a longer heating time than a rapid thermal anneal step which may for example and without limitation heat the substrate composition for less than a minute, e.g., 30 seconds.

The top surface of substrate composition is polished with CMP to remove the semiconductor material layer over the portions of the substrate composition not in the ESD trench 402 forming the final shape of the ESD semiconductor material layer 418. Nitride layer 413 and upper ESD layer 414 are etched away from areas of the substrate composition not covered by the ESD semiconductor material layer 418 after CMP as shown in FIG. 4H. The oxide material on the top surface of substrate composition 419 is protected by the nitride layer which may act as an etch stop. As can be seen the CMP reveals a depression in the surface of the ESD trench semiconductor material 418 where the polishing wheel could not remove material because the semiconductor material was below the top surface of the semiconductor substrate. Additionally, one or more ESD Contact 417 regions are formed in the semiconductor material 418. If more than one ESD contact region is formed the regions may be separated by sufficient space to allow each region to function as a junction diode without interference from other ESD contact regions. Alternatively, this step may be carried out at the same time forming the source region.

Finally, as shown in FIG. 4I the substrate 401 may optionally be doped with ions of the first conductivity type to form a JFET region 430 via ion implantation and a pre-body thermal drive is then performed these steps are omitted in formation of a single gate electrode transistor. Next the substrate 401 is implanted with ions of the second conductivity type forming body region 422 which then is subjected to rapid thermal annealing to further drive the ions into the substrate. One or more Source regions 423 are then implanted into the body regions near a side of an active gate trench 403 with a heavy dopant concentration. The semiconductor composition is then heated to drive the dopants in the source region 423 to diffuse deeper into the body region 422 and to diffuse the ESD Contact 417 regions further throughout the ESD semiconductor material 418. Low temperature oxide (LTO) is then grown over the surface of the substrate composition followed by deposition of Borophosphosilicate Glass (BPSG) and heating of the BPSG to flow the insulator layer over the substrate composition to form the top portion of the ESD trench insulation layer 420 and the top gate insulation layer 424. The BPSG may also insulate portions of the substrate composition over the body regions.

Vias in the BPSG layer may be created via etching or mechanical drilling for the source contact and the ESD contact. Next one or more ESD direct contact regions 431 are heavily doped into the ESD contact regions 417 with ions of the second conductivity type followed by rapid thermal annealing to diffuse the ions into the ESD contact region causing a gradient drop off in concentration moving away from the top of the ESD contact. Finally, a conductive material 421 such as a metal layer may be deposited over the insulation layers and in the vias to make contact with the source region 423, body region 422 and ESD trench contact regions 417. The conductive material 421 is subsequently etched to create the final layout of conductive material on the substrate composition. The result is a transistor device having improved ESD trench with nitride layer and a depression on the surface interface of the ESD semiconductor layer according to an aspect of the present disclosure.

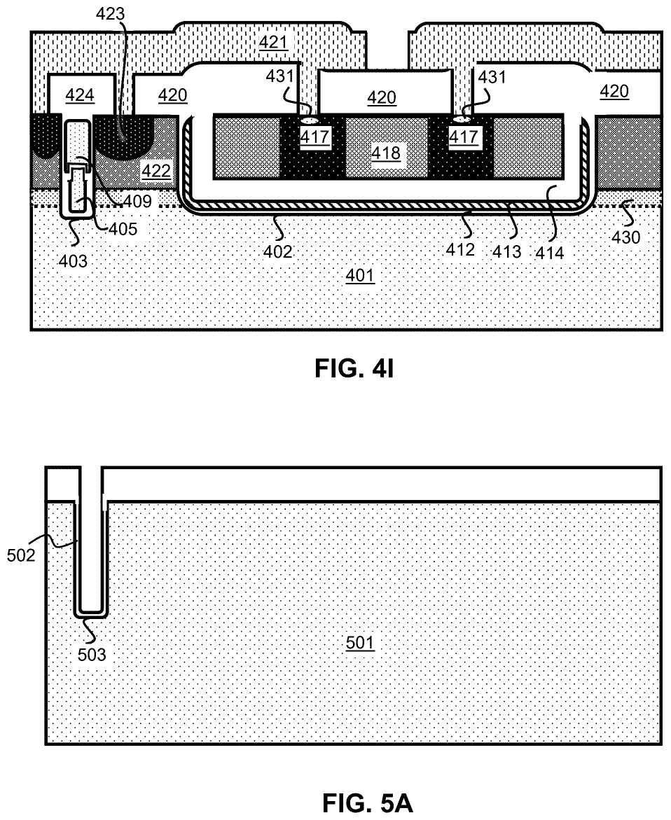

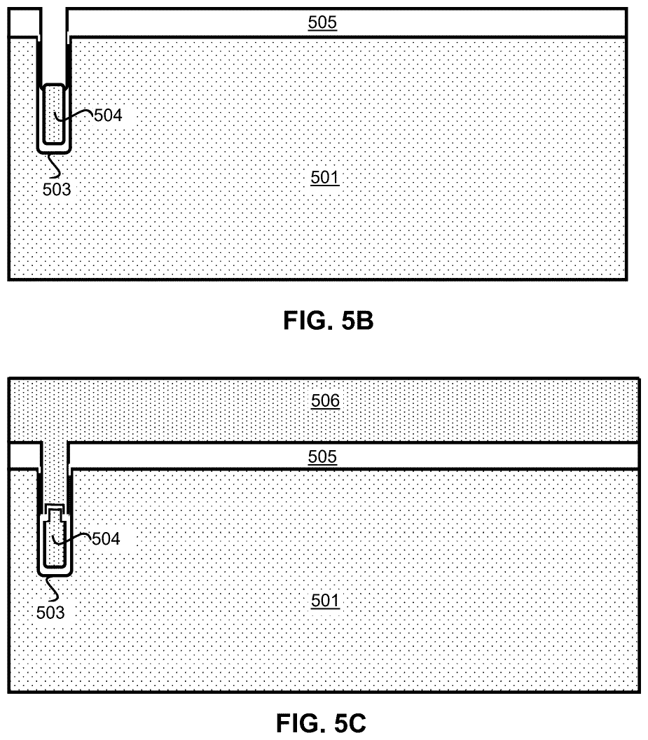

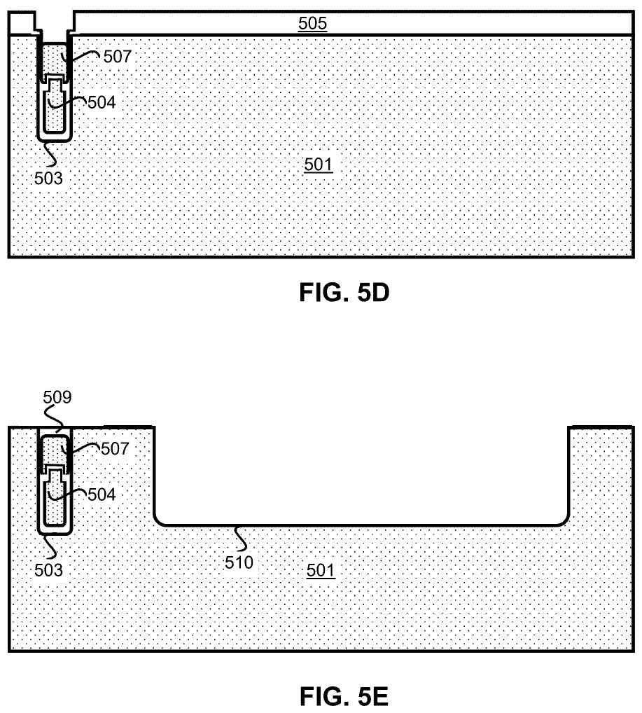

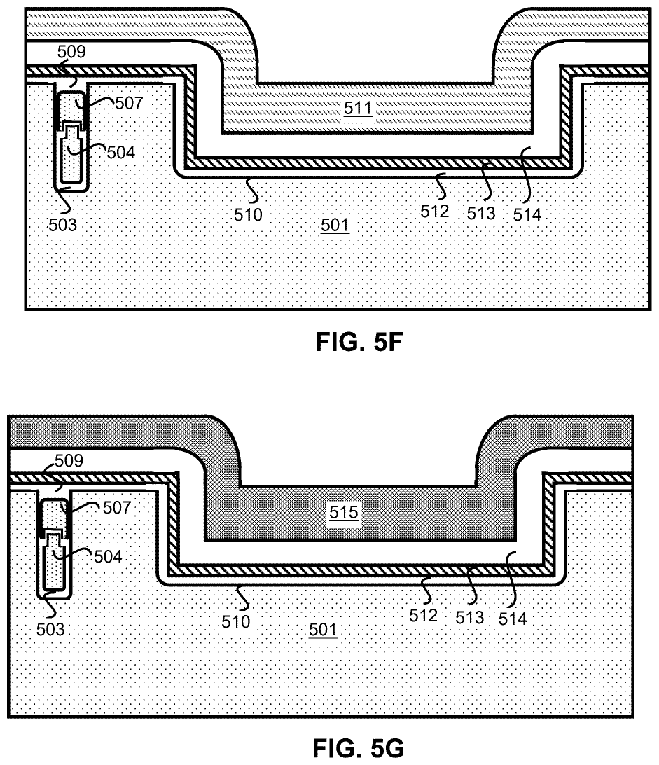

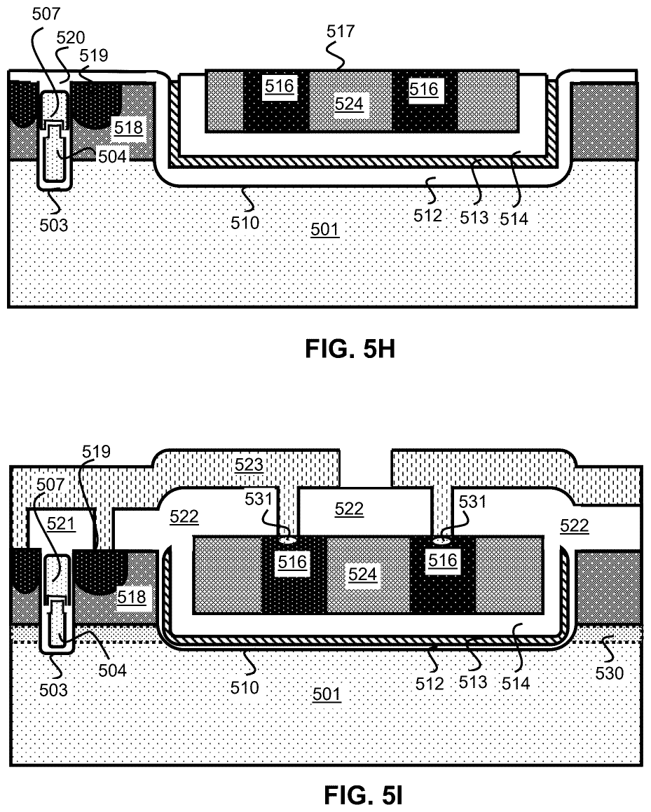

FIG. 5A-5i depicts an example of a method of fabrication of an improved transistor device with nitride layer and an active region gate trench that runs deeper into the semiconductor substrate than the ESD trench layer of the type shown in FIG. 2. In this fabrication method the active gate trench 503 is formed before forming the ESD trench as depicted in FIG. 5A. A semiconductor substrate 501 may be provided that includes an epitaxial layer lightly doped with ions of a first conductivity type formed on top of a heavily doped layer of the first conductivity. The semiconductor substrate 501 is masked with an oxide hard mask and then Active Gate trench 503 are etched by a suitable trench formation method for example and without limitation reactive ion etching. After etching the active gate trenches, an oxide layer 502 is deposited over the top surface of the substrate composition including the exposed surfaces in the trenches via thermal oxidation and/or CVD. Next a blanket n-doped polysilicon layer is deposited over the entire exposed top surface of the substrate composition to form the lower active gate polysilicon layer 504 in the active trench 503. The blanket n-doped polysilicon layer is dry etched, and the oxide layer is wet etched back within an upper portion of the active gate trench 503 as shown in FIG. 5B.

In single gate electrode implementations, the lower active gate polysilicon may be etched away in the active gate trench after liner oxide is wet etched to remove oxide on the upper side wall of the trench, but this step may be omitted in SGT transistor fabrication. An inter-poly oxide on top of the shield electrode 504 may be formed by thermal oxidizing the top surface of the polysilicon shield electrode 504. A gate oxide layer is then grown on the sides of the active gate trench 503 by thermal oxidation. Next an n-doped polysilicon layer 506 is deposited over the top surface of the substrate composition including in the Active gate trench 503 as shown in FIG. 5C. This will form the upper Active gate layer and may be formed by any suitable deposition method such as chemical vapor deposition (CVD), Physical Vapor Deposition (PVD) etc. As shown in FIG. 5D the polysilicon layer is wet etched and etched back away from the top surface of the substrate composition including leaving the top gate electrode layer 507 in gate trench 503.

An oxide hard mask is deposited over the exposed surface of the substrate composition by any suitable deposition method for example and without limitation CVD. Then an ESD Trench mask is formed over the surface of the substrate composition. The ESD trench mask may be any suitable mask for example and without limitation a patterned photomask or mechanically applied patterned mask. The ESD trench 510 is etched through gaps in the patterned mask. The ESD trench may be formed by any suitable etching method for example and without limitation Reactive Ion Etching (RIE) or wet etch. The oxide 505 is then removed from the top surface of the substrate composition via chemical and mechanical polishing (CMP). As shown in FIG. 5E the result is a formed active gate having an upper portion of the active gate electrode 507 and a lower portion of shield electrode 504 insulated from the substrate by gate electrode insulation layer 509 in the active gate trench 503 and a bare ESD trench 510. As a result of this process the ESD trench 510 is less deep than the active gate trench 503. Additionally compared to the ESD trench 402 implementation shown in FIG. 4A-4I, the ESD trench here 503 is shallower. This is due to manufacturing details but as discussed above in this implementation the ESD trench may be any depth because it is formed independently of the active gate trench. Note that the active gate insulation layer 509 is thicker near the bottom of the active gate trench than near the top.

Next FIG. 5F shows an additional oxide material deposited over the surface of the substrate composition forming the full lower ESD trench oxide layer 512 in the ESD trench, followed by deposition of a nitride layer 513. Then an upper ESD oxide layer 514 is deposited in the ESD trench 510 and over the top surface of the substrate composition. Finally, ESD semiconductor layer 511 is deposited over the upper ESD oxide layer 514 in the ESD trench 510 and over the top surface of the substrate composition. The ESD semiconductor layer 511, upper ESD insulation layer 514, nitride layer 513 and lower ESD insulation layer 512 may be formed by any suitable deposition method for example and without limitation CVD. The ESD semiconductor layer 511 may be undoped polycrystalline silicon, which is subsequently doped with ions of the second conductivity type as shown in FIG. 5G. The doped ESD semiconductor layer 515 is heated to drive the ions of the second conductivity type to diffuse throughout the semiconductor layer.

The top surface of substrate composition is polished with CMP to remove the semiconductor material layer over the portions of the substrate composition not in the ESD trench 510 forming the final shape of the ESD semiconductor layer 524. Nitride layer 513 and upper ESD layer 514 are etched away from areas of the substrate composition not covered by the ESD semiconductor layer 524 after CMP as shown in FIG. 5H. The silicon oxide material 520 formed during deposition of lower ESD insulation layer 512 on the top surface of the substrate composition is protected by the nitride layer 513 which may act as an etch stop. The substrate 501 may optionally doped with ions of the first conductivity type to form a JFET region 530 via ion implantation and a pre-body thermal drive is then performed these steps are omitted in formation of a single gate electrode transistor. Next, the body region 518 is implanted with ions of the second conductivity type into the substrate 501 and then a rapid thermal annealing is performed to further drive the ions into the substrate. One or more Source regions 519 are then implanted into the body regions near a side of an active gate trench 503 with a heavy dopant concentration. Additionally, one or more ESD Contact 517 regions are formed in the semiconductor material 518. If more than one ESD contact region is formed the regions may be separated by sufficient space to allow each region to function as a junction diode without interference from other ESD contact regions. The semiconductor composition is then heated to drive the dopants in the source region to diffuse deeper into the body region.

Finally, as shown in FIG. 5I Low temperature oxide (LTO) is then grown over the surface of the substrate composition followed by deposition of Borophosphosilicate Glass (BPSG) and heating of the BPSG to flow the insulator layer over the substrate composition to form the top portion of the ESD trench insulation layer 522 and the top gate insulation layer 521. The BPSG may also insulate portions of the substrate composition over the body regions.

Vias in the BPSG layer may be created via etching or mechanical drilling for the source contact and the ESD contact. Next one or more ESD direct contact regions 531 are heavily doped into the ESD contact region 516 with ions of the first conductivity type followed by rapid thermal annealing to diffuse the ions deeper into the ESD contact region. Finally, a conductive material 523 such as a metal layer may be deposited over the insulation layers and in the vias to make contact with the source region 519, body region 518 and ESD trench contact regions 516. The conductive material may be masked and etched to form the final layout of the conductive material layer 523. The result of the foregoing process is a transistor device having improved ESD trench with nitride layer and an active region gate trench that runs deeper into the semiconductor substrate than the ESD trench according to an aspect of the present disclosure.

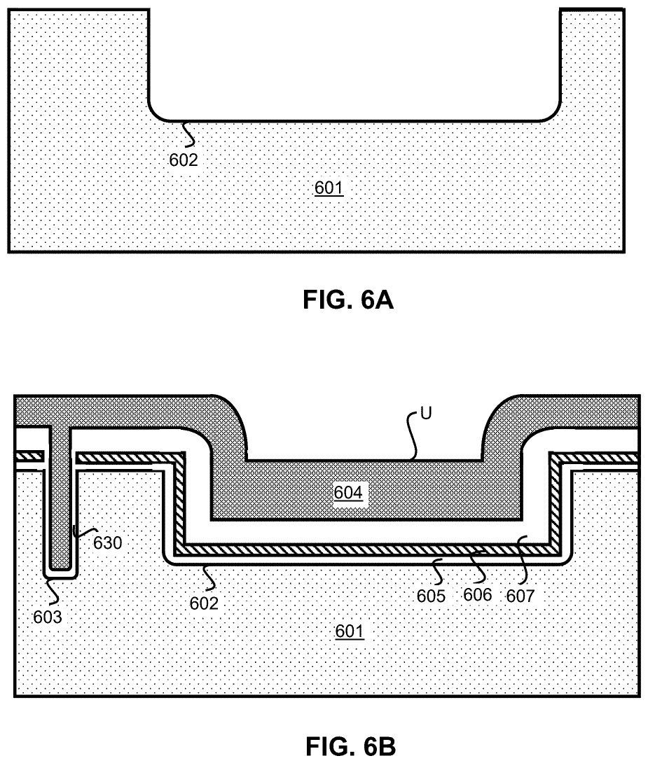

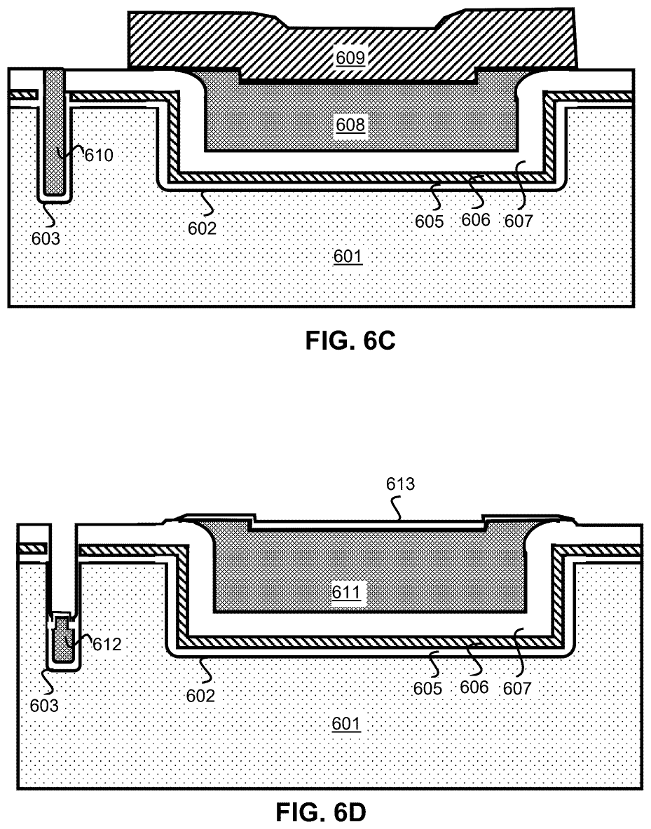

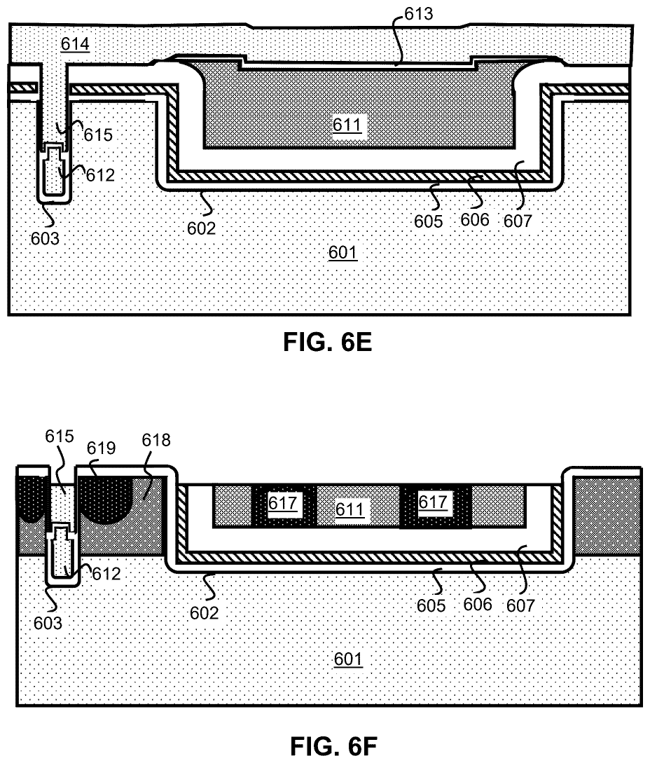

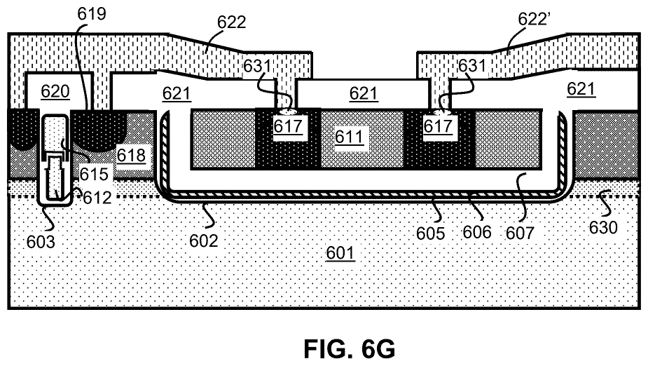

FIGS. 6A-6G depict an example of a method of fabrication of a transistor device of the type shown in FIG. 3 having improved ESD trench with nitride layer having an active region formed prior to the formation of the ESD trench. As depicted in FIG. 6A, the ESD trench 602 is formed in a semiconductor substrate 601 before forming the Active Gate trench. A semiconductor substrate 601 may be provided that includes an epitaxial layer lightly doped with ions of a first conductivity type formed on top of a heavily dope layer of the first conductivity. The semiconductor substrate 601 is masked with an oxide hard mask and then ESD trench 602 is etched by a suitable trench formation method for example and without limitation reactive ion etching.

After etching the ESD trenches a Lower ESD trench insulation layer 605 is deposited over the top surface of the substrate composition including the exposed surfaces in the trenches. A nitride layer 606 is deposited over the Lower ESD trench insulation layer 605. Next an upper ESD trench insulation layer 606 may be deposited over the nitride layer 606. The nitride layer may be masked and patterned for the active gate trench by any suitable type of mask and patterning method for example and without limitation, photoresist mask or mechanically applied patterned mask. After masking the active gate trench 603 is etched into the semiconductor substrate 601 by any suitable etching method for example and without limitation, an anisotropic etching process, such as RIE.

Then, gate insulation 630 may be deposited over the top surface of the substrate composition and in the active gate trenches 603. The deposited gate insulation material may increase the thickness of the top ESD trench insulation layer 607 in the ESD trench 602 and on the top surface of the substrate composition. The Lower ESD trench insulation layer 605, nitride layer 606, and ESD trench insulation layer 606 may be made from for example and without limitation silicon dioxide and formed via suitable method such as CVP. Next, a blanket un-doped polysilicon layer 604 is deposited over the entire exposed top surface of the substrate composition to form the precursor ESD semiconductor layer in the ESD trench 602. Finally, an upper portion U of the undoped polysilicon layer 604 may be implanted with ions of the second conductivity type and then the substrate composition may be heated to drive the ions deeper into the precursor ESD semiconductor layer at a subsequent stage of processing. The result is the composition of matter shown in FIG. 6B.

After doping and thermal drive, the top surface of the substrate composition may optionally be polished via CMP to remove polysilicon material not located in the ESD trench 602 or Active Gate trench 603. An ESD mask 609 is then formed over the top surface of the ESD semiconductor layer 608 as shown in FIG. 6C. The ESD mask 609 may be any suitable type of patterned mask applied by any suitable mask application and patterning method for example and without limitation a patterned photoresist mask.

The oxide layer 607 is then etched back from the exposed surface of the substrate composition including around the polysilicon material 610 in the gate trench using any suitable insulation layer etchant. A polysilicon etch is then applied to the substrate composition removing the semiconductor material form the active gate trench 603 leaving the undoped polysilicon material in the bottom of the active gate trench which forms the Shield electrode 612. As an option, an N type implant may be carried out to dope the shield electrode 612. In implementations with a single gate electrode, a different mask is used during the polysilicon etch and the material that would form the shield electrode is etched away instead. After the polysilicon etch the ESD mask 609 is removed via any suitable method, for example chemical wash and/or CMP.

After removal of the ESD mask 609 the liner oxide 607 is further wet etched with any suitable etchant to generate the desired thickness for the bottom insulator walls of the Active gate trench 603. Next an oxide layer is grown on the sidewalls of the active gate trench, over top the shield electrode 612 and over the top surface of the substrate and on top 613 of ESD semiconductor layer 611 via thermal oxidation as shown in FIG. 6D.

Next an n-doped polysilicon layer 614 is blanket deposited over the top surface of the substrate composition including over the oxide layer 613 in the ESD trench and in the Active gate trench as shown in FIG. 6E. This will form the Active Gate electrode 615 after etching. N-doped polysilicon layer 614 may be deposited by any suitable method, for example and without limitation CVD.

Portions of the n-doped polysilicon layer 614 and upper ESD insulation layer 607 are removed from the top surface of the substrate composition via CMP. The nitride layer 606 is then wet etched via any suitable nitride etching process to remove the nitride layer 606 from the top surface of the substrate composition leaving the lower ESD insulation layer exposed on the top surface of the of the substrate composition. Additionally, the polishing process removes the oxide layer 613 and a portion of the ESD semiconductor layer 611 leaving a relatively flat top surface of the ESD Semiconductor layer 611. Note here that the ESD semiconductor layer and ESD trench profile protects the upper ESD insulation layer 607 and nitride layer 606 in the ESD trench from being removed.

The oxide layer is then etched back from the surface of the substrate composition via any suitable etch back method. In implementations with a shield electrode, the substrate 601 may optionally be doped with ions of the first conductivity type to form a JFET region 630 via ion implantation and a pre-body thermal drive is then performed these steps are omitted in formation of a single gate electrode transistor. Next, the substrate 601 is doped via ion implantation with ions of the second conductivity type to form body regions 618. The substrate composition is then subjected to rapid thermal annealing to complete the body regions. Source regions 619 are formed in the body region 618 near the active gate trench 603 by ion implantation of ions of the first conductivity type (e.g., n-type ions) at a heavy dopant concentration. Additionally, one or more ESD Contact 617 regions are formed in the ESD semiconductor material 611. If more than one ESD contact region is formed the regions may be separated by sufficient space to allow each region to function as a junction diode without interference from other ESD contact regions. The substrate composition is then heated to drive source region ions to diffuse into the body region and diffuse the ESD contact regions 617 into the ESD semiconductor material 611. Thus, resulting in the composition of matter shown in FIG. 6F.

As shown in FIG. 6G Low temperature oxide (LTO) is grown over the surface of the substrate composition followed by deposition of Borophosphosilicate Glass (BPSG) and heating of the BPSG to flow the insulator layer over the substrate composition to form the top portion of the ESD trench insulation layer 621 and the top gate insulation layer 620. The BPSG may also insulate portions of the substrate composition over the body regions.

Vias in the BPSG layer may be created via etching or mechanical drilling for the source contact and the ESD contact. Next one or more ESD direct contact regions 631 are doped into the ESD contact regions 617 heavily with ions of the second conductivity type followed by rapid thermal annealing to diffuse the ions deeper into the ESD contact regions 617. Finally, a conductive material 622 such as a metal layer may be deposited over the insulation layers and in the vias to make contact with the source region 619, body region 618 and ESD trench contact regions 617. The conductive material may be masked and etched to form the final layout of the conductive material layer 622. The result of the foregoing process is a transistor device having improved ESD trench with nitride layer having an active region formed prior to the formation of the ESD trench according to an aspect of the present disclosure.

Thus, may be fabricated a transistor device with thick bottom insulation plus nitride layer that improves the resistance of the ESD structure to leakage of high voltage transients into the active area, reducing the area of the substrate required for ESD trenches.

While the above is a complete description of the preferred embodiment of the present invention, it is possible to use various alternatives, modifications, and equivalents. Therefore, the scope of the present invention should be determined not with reference to the above description but should, instead, be determined with reference to the appended claims, along with their full scope of equivalents. Any feature described herein, whether preferred or not, may be combined with any other feature described herein, whether preferred or not. In the claims that follow, the indefinite article “A.” or “An” refers to a quantity of one or more of the item following the article, except where expressly stated otherwise. The appended claims are not to be interpreted as including means-plus-function limitations, unless such a limitation is explicitly recited in a given claim using the phrase “means for.”

What is claimed is:

1. A method for fabrication of a trench transistor with electrostatic discharge protection in trench, comprising the steps of:
a) forming an Electrostatic Discharge Protection (ESD) trench in a semiconductor substrate wherein the semiconductor substrate includes ions of a first conductivity type and wherein the ions of the first conductivity are opposite ions of a second conductivity type;
b) forming a lower insulation layer with a an insulating material over the semiconductor substrate in the ESD trench;
c) depositing a nitride layer over the lower insulation layer in the ESD Trench of the semiconductor substrate;
d) depositing a semiconductor ESD layer over the nitride layer in the ESD trench.

2. The method of claim 1, further comprising forming an oxide layer over the nitride layer before depositing the semiconductor ESD layer.

3. The method of claim 1 wherein a) further comprises forming an active trench in the semiconductor substrate along with the ESD trench.

4. The method of claim 1, further comprising forming an active trench before forming the ESD trench.

5. The method of claim 4, further comprising depositing an active trench insulation layer into the active trench in the semiconductor substrate before forming the ESD trench.

6. The method of claim 5, further comprising forming a gate conductive electrode in the active trench before forming the ESD trench.

7. The method of claim 1, further comprising e) doping the semiconductor ESD layer with ions of the second conductivity type.

8. The method of claim 7, further comprising, f) doping one or more ESD contact regions in the semiconductor ESD layer with ions of the first conductivity type.

9. The method of claim 1, further comprising forming an active trench after forming the ESD trench.

10. The method of claim 9, further comprising polishing a top surface of the substrate to remove the semiconductor ESD layer from the top surface of the substrate leaving semiconductor ESD layer material in the ESD trench and applying ESD etch mask over the semiconductor ESD layer material after polishing a top surface of the substrate.

11. The method of claim 9, further comprising applying ESD etch mask over the semiconductor ESD layer material after polishing a top surface of the substrate.

12. The method of claim 9, further comprising etching away ESD semiconductor layer material from the active trench.

13. The method of claim 12, further comprising depositing conductive material in the ESD with deposition of gate electrode material.

14. The method of claim 1, further comprising forming an ESD top insulation layer over the ESD semiconductor layer and forming a source metal layer wherein the ESD top insulation layer includes one or more spaces wherein the source metal layer contacts the ESD semiconductor layer.

15. The method of claim 1, further comprising forming an upper insulation layer with an insulating material on the nitride layer and wherein the ESD semiconductor layer is formed on the upper insulation layer.

16. A composition of matter, comprising:
a semiconductor substrate including ions of a first conductivity type wherein the ions of the first conductivity are opposite ions of a second conductivity type;
an Electrostatic Discharge Protection (ESD) trench formed in the semiconductor substrate;
a lower insulation layer formed over a surface of the ESD trench in the semiconductor substrate;
a nitride layer formed over the lower insulation layer in the ESD trench;
an upper insulation formed on the nitride layer in the ESD trench; and
a ESD semiconductor layer formed on the upper insulation layer.

17. The composition of matter of claim 16 wherein an active trench runs deeper into the semiconductor substrate than the ESD trench.

18. The composition of matter of claim 16 wherein the ESD semiconductor includes a depression at the top surface interface.

19. The composition of matter of claim 16 wherein the nitride layer is located only in the ESD trench.

20. The composition of matter of claim 16 wherein the ESD semiconductor layer is doped with ions of the second conductivity type and includes one or more ESD contact regions doped with ions of the first conductivity type wherein the ESD contact region functions as a cathode for a junction diode formed between the ESD contact region and the ESD semiconductor layer, wherein the ESD semiconductor layer acts as the anode.
